(19) United States
(12) Patent Application Publication
(10) Pub. No.: US 2006/0200720 A1
(43) Pub. Date: Sep. 7, 2006

(54) Generating and verifying read and write cycles in a PCI bus system

(76) Inventors: David Grimme, Houston, TX (US); Mark Hammons, Magnolia, TX (US); Steven Chan, Houston, TX (US); Robert D. Matthews, Sugar Land, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/070,638

(22) Filed: Mar. 1, 2005

(51) Int. Cl. G01R 31/28

(52) U.S. Cl. 714/738

(57) ABSTRACT

A peripheral device to generate read and write cycles on a PCI bus comprises a PCI bus interface. A control unit has a data pattern generator to source a data pattern to a target via the interface during a write operation and to verify an incoming data pattern from the interface during a read operation.

### FIELD

The present invention relates generally to data communications in a PCI bus system. More specifically the invention concerns a peripheral device for generating and verifying data read from an external source and data written to an external target. In other aspects it also concerns a method for verifying read cycles on a PCI bus, and a computer program.

### BACKGROUND

Previous systems have used memory on a peripheral device to store data read from an external source and to store data to be written to an external target.

The system processor is required to initialize the entire buffer on the peripheral device before conducting an external read. The processor is also required to initialize the entire buffer and write the entire buffer before conducting an external write. Even though the peripheral device may read data rapidly, for example PCI bursting at 1 datum per clock, the processor is often very slow to read from the device, or write to the device, and uses non-burst transactions from the system's bridge device. This all tends to slow communications.

Further delays are introduced when it is necessary to verify the data written from an external source and read into the peripheral device. In this event the processor must read the entire buffer out of the peripheral device and then verify it against a test pattern. Since verification occurs after the peripheral device has completed transferring its entire buffer, a later trigger must be used to capture any verification failure making it difficult to retrace and find the actual error.

### SUMMARY

A peripheral device to generate read and write cycles on a PCI bus comprises a PCI bus interface, and a control unit. The control unit has a data pattern generator to source a data pattern to a target via the interface during a write operation, and to verify an incoming data pattern from the interface during a read operation.

### BRIEF DESCRIPTION OF THE DRAWINGS

FIG. 1(A) is a schematic block diagram of a peripheral device, in accordance with an embodiment of the invention, using a PCI bus;

FIG. 1(B) is a more detailed block diagram of the device of FIG. 1(A) showing the various connections to an external memory unit and the PCI bus; and

FIG. 2 is a flow diagram showing the processes that software associated with a system undertakes in order to verify data or programming the device with data to write.

### DETAILED DESCRIPTION OF EXEMPLARY EMBODIMENTS

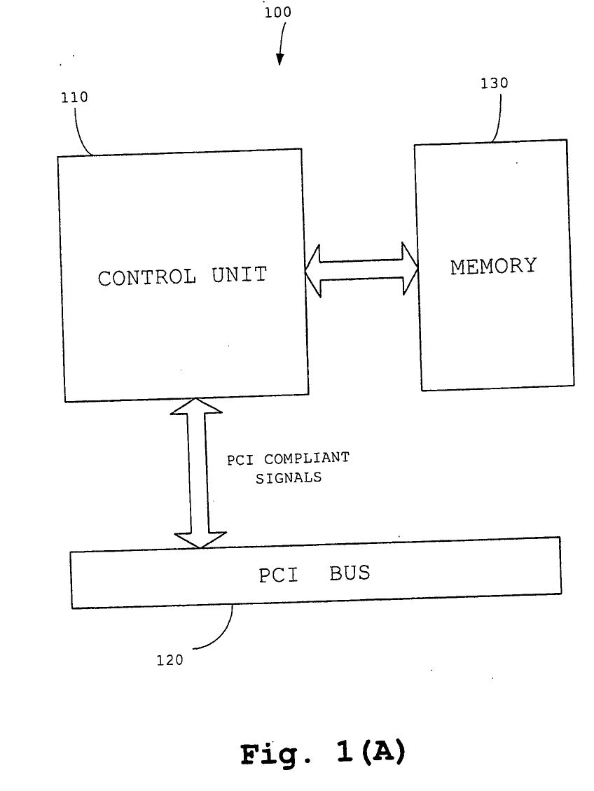

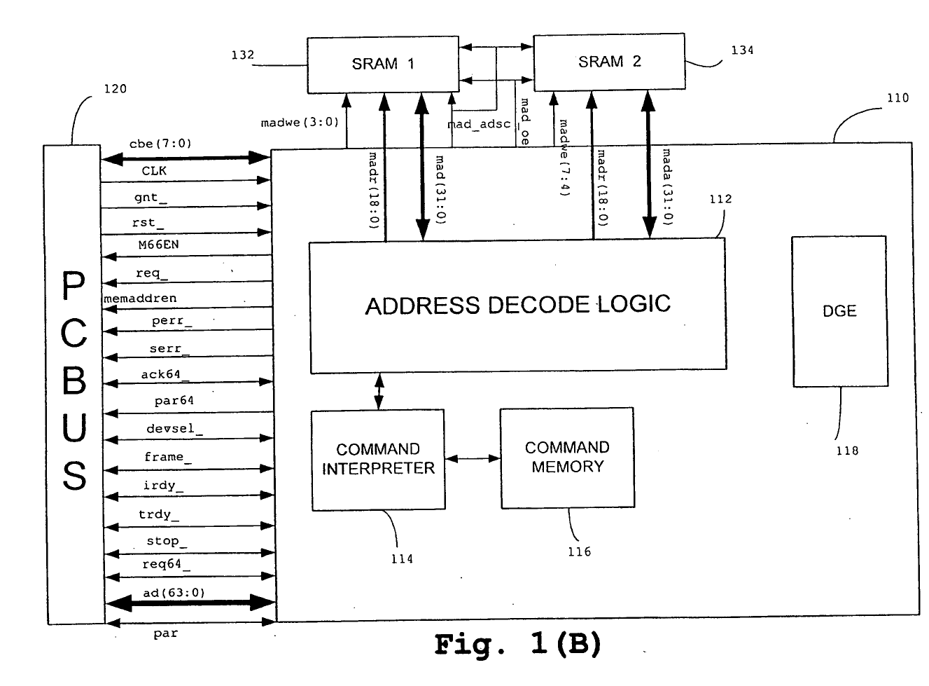

Referring to FIG. 1(A), a peripheral test device, in accordance with an embodiment of the invention, comprises a circuit board 100 adapted to be inserted into a PCI slot on a system that is to be tested.

The board 100 can be configured as both a Master (initiator) and Slave (target) device. This is in order so that the board 100 can verify data that a peripheral device reads or to program the peripheral device with data to write to a PCI bus.

The Master cannot perform transfers to its own Slave. Therefore for Master to Slave transfers, two boards 100 will be required. However in all other tests, for example from the board 100 to or from a host CPU or through a bus bridge, will only require one board 100. In some cases more than one CPI slot will be required to fully test the system. Thus in particular the board 100 is designed primarily to test 64-bit PCI transfer modes running at 66 MHz.

The board 100 is a PCI66DG board and is a 64-bit version of the PCI Master/Slave Board (PCIMS) that is currently being used to test the PCI bus interface in peripheral devices of the applicant. The board 100 is intended to run at 66 MHz bus speed. The board 100 does however provide support for a 32-bit PCI data transfer as well. The main components of the board 100 are a control unit 110, a PCI bus 120 and a memory 130.

The control unit 110 includes an address decode logic unit, a command interpreter unit and a command memory as will be described in more detail with reference to FIG. 1(B). The control unit 110 is essentially a field programmable gate array or FPGA and provides all the functionality of the board 100. A particular embodiment is the Altera EP1S10F780C6. It is packaged in a 780 pin FineLine BGA. The control unit is programmed using standard PCI bus memory cycles. The control unit 110 includes Master and Slave state machines to support the board's functions.

The memory unit 130 comprises 4 MB of storage and is used for emulating a Slave, or target, device. It consists of two blocks of SRAM 132 and 134 that each have 256K of memory space and as a 32-bit I/O the 256K of memory space is shared at the bottom of the same memory space. Thus a total of 4 MB memory can be used for access to the peripheral device as a PCI memory target.

The address decode logic unit 112 is used when the board 100 is addressed as the Slave. A memory base register is used to provide the base address for accessing the external memory units 132 and 134. The decoding logic also uses a configuration memory base register as the base address for programming the internal instruction queue and to provide an alternative channel for programming the configuration space through memory transaction. When the board's configuration space and the instruction queue is accessed, the decoding logic will only allow a single data phase for each transaction. When either external memory unit 132 or 134 is addressed, the board 100 can support burst transaction.

The command interpreter unit 114 is used for the operation of the PCI Master state machine. The interpreter 114 fetches commands from the command memory/instruction queue 116 and interprets each command. The command memory/instruction queue 116 is located within the control unit 110 internal SRAM. The command memory 116 includes memory of 256 192-bit instructions of commands and programmable parameters for all Master or initiator transactions. This is implemented using the embedded SRAM available within the control unit 110. Due to historical reasons, the 192-bit instruction is separated into three parts being the instruction queue, the extended instruction queue and the extended address queue. It takes three memory regions for programming. The extended address queue is only needed to specify addresses above 4 TB (42 bits).

A data generator engine 118 is shown as part of the control unit 110 and can act either as a state machine or a processor on the peripheral device to generate data or verify data dynamically as a transfer occurs. Software is used to program and verify the peripheral device. Using a data generator engine 118 on a peripheral device, that is in the control unit 110, reduces the amount of programming that needs to be done to the device and the number of cycles in order to verify transfers. Rather than program the device with 1 MB for every MB that it will transfer, the system only needs to program the device with the pattern type and seed values.

In acting as a data pattern generator, the data generator engine may verify incoming data transmitted on the system PCI bus 120 during the read operation. There are three data patterns being incremental pattern (repetitive addition), random pattern (pseudo-random) and a toggle pattern. In generating an incremental pattern, the generator bases this on continual increment to the base pattern register. The data generator operates in a purely sequential manner. Its operation is independent of the address or read/write transaction type. The first output from the generator is the base pattern.

In order to generate a random pattern, a random seed is required to be provided by software. The random seed is stored in the base register. The first output from the random generator is the seed itself and at the end of all the transactions the base register will latch the next out-going random number. The random pattern generator also operates in a purely sequential manner.

To generate a toggle pattern the generator utilizes the base register and the incremental register to provide the two toggling patterns. If a 32-bit Master is used, both the pattern A and B registers are needed to be set to the same value. If a 64-bit Master is chosen, then both the pattern A and B registers will be used. The generator operates in a sequential manner.

When the board is acting as the Master, via a Master state machine, a data verification and recording mechanism is enabled during the read transaction. Thus the incoming data will be compared to the pattern generated by the data pattern generator of the data generator engine. If the data is inconsistent and does not match, the offending address and the data will be recorded in the internal registers. Thus during the read transaction, the data generator provides reference data to compare with the incoming data. If a mismatch occurs then both the address and the data of the first occurrence of error will be logged and stored in the internal registers.

In order to support a O-wait state during the Master write/read burst transactions, the data pattern generators are designed to source the data to target during the write operation and verify the incoming data during the read operation.

The following description provides details on local address maps, local registers, the configuration space and command memory associated with the control unit 110.

The address map below shows the locations of the various memory and control buffers for the test board 100:

| | PCI: ADDRESS OFFSET FROM |
|---|---|
| | MEMORY BASE ADDRESS |
| DEFINITION | (BAR0) |
| PCI Target WR/RD DATA BUFFER | 0000:0000 |
| (LOW) | |
| PCI Target WR/RD DATA BUFFER | 003F:FFFF |
| (HIGH) | |

| | PCI: ADDRESS OFFSET |
|---|---|
| | FROM CONFIGURATION |
| | MEMORY BASE |
| DEFINITION | ADDRESS (BAR2) |
| INSTRUCTION QUEUE (LOW) | 0000:0000 |
| INSTRUCTION QUEUE (HIGH) | 0000:07FF |
| EXTENDED INSTRUCTION QUEUE | 0000:0800 |
| (LOW) | |
| EXTENDED INSTRUCTION QUEUE | 0000:0FFF |
| (HIGH) | |
| NEW ADDRESS INSTRUCTION | 0000:1000 |
| QUEUE (LOW) | |
| NEW ADDRESS INSTRUCTION | 0000:17FF |
| QUEUE (HIGH) | |
| Configuration Alias Space | 0000:8000 + Configuration |
| | register address |

The PCI target data buffer has a 4 MB range starting from the address specified in a memory base address register which is a 64-bit address register.

The instruction queue, low and high, is 256 qwords deep and contains instructions used by the initiator when performing the test. The PCI instruction type and format are shown in the table below. The starting address is specified in the configuration memory base address register (BAR).

Reserved (63:32) was A[31:0]

| CMD[3:0] | T | BE[7:0] | DAC | TBD | S | P | L | P2 | Reserved[9:0] |
|---|---|---|---|---|---|---|---|---|---|
| (31.28) | (27) | (26:19) | (18) | | (13) | (12) | (11) | (10) | was A[41.32] |

The bit field 63:32 is reserved for backward compatibility. It was previously the A(31:0) field during the address phase OR'ed with the extended address instruction queue to produce A(31:0). Bit field 31:28 is the PCI command type. The Device Type (1:0) and the Req 64_ena bit in the configuration register 0xA4 will qualify as either a 32 or a 64-bit mode in operation. Bit 27 is the terminate bit and is 0 for normal operation and a 1 for stop execution operation. When it is 1 the instruction containing the T bit will not be executed and INTA can be sent with appropriate set up by setting Intx_disable=0 and Inta_control=1.

Bit field 26:19 is byte enabled for transaction. It provides the BE pattern between the first and the last data phase. This field only applies when there are three or more data phases. The two sets of nibbles in this bit field need not be the same and for a 32-bit master, only bit field (22:19) is used. If the single data phase bit is enabled then this field will be ignored. Bit 18 is the dual address cycle and this is a qualified bit for the address bits (40:32) field. With the dual address cycle equal to 1 that particular cycle will run.

Bit field 17:14 is still to be determined and bit 13 relates to a single data phase. It is a modified bit for the length/iteration register. For MSI operation, the single data phase bit needs to be 0. When it is 0 the Master will perform a single burst transaction to the target. The length/iteration field will set the total number of quadword/dword (64/32 bit Master) transfer during the burst transfer. It will be set to 1 whereby the Master will perform a sequence of single 64/32 bit data transactions to the target with total number of single transactions set by the length/iteration register. The address of each single data transaction will be updated accordingly. When this bit is enabled, the single data phase transaction will only use the Start_BE (7:0) for each transaction.

Bit 12 is a pause bit. It will be set to 1 such that the Master will pause after the execution of the current instruction. The Master will wait for a memory read/write activity before proceeding to the next instruction.

Bit 11 is a loop bit and will be set to 1 such that the Master will loop back to the beginning of the instruction queue once it completes the current instruction. Bit 10 is the Pause2 bit and will be set to 1 whereby the Master will stay at the same instruction until the following condition is met: target abort, devsel_expiration, or AD(0) received is 0. Note this function can only be used on a read transaction with only one data phase.

Bit field 9:0 is reserved and previously was the A(41:32) field during the dual address phase which was OR'ed with the extended address instruction queue to produce the A(41:32). It is reserved for backward compatibility.

All of the bit fields 31 through to 10 are read/write bits.

With regard to the extended instruction queue, low and high in configuration memory base register (BAR2), it is 256 qwords deep and contains the extended instructions used by the initiator when performing the test. The PCI instruction type and the format are shown in the table below. The starting address is the configuration memory base address+x800.

Length (63.32)/Iteration (47:32)

| Not used | MSI Enable | End_BE[7:0] | Start_BE[7:0] |
|---|---|---|---|
| | (16) | (15:8) | (7:0) |

The bit fields 63:32/47:32 are the length/iteration bits. This register is modified by the single data phase bit in the instruction. If the S bit is 0 then this register will indicate the following:

Bit field (61:32) indicates the length of transfer in DWORDS for 32 bit Master transfer. If a 0 value is in this field, it indicates 4 gigabytes of transfer;

Bit field (60:32) indicates the length of transfer in QUADWORDS for 64 bit Master transfers. If a 0 value is in this field in indicates 4 gigabytes of transfer.

If S bit is 1 this register field (47:32) alone will indicate the total number of the single data phase transfers for this current instruction. The value of 0 in the length means a real operational value of 4 gigabytes. For MSI operation this field needs to have a value of 1.

The bit field 31:15 is reserved and the bit 16 is the MSI bit that indicates the instruction as being an MSI transaction.

Bit field 15:8 is the End_BE(7:0) bit field. For 64-bit Master transfer, this is the ending BE pattern for the last data phase. For 32-bit Master transfer only bit (3:0) is used. This register applies if there are two or more data phases in the transaction. If a single data phase bit is set then this field will be ignored.

The bit field 7:0 is a Start_BE(7:0) bit field. For 64 bit Master transfer, this is the starting BE pattern for the first data phase. Start_BE will be used for the transfer. For 32 bit master transfer only the nibble (3:0) is used. This register applies if there is one or more data phases in the transaction.

All bit fields are read/write.

With regard to the extended address instruction queue, in the configuration memory base address register number 2 (BAR2) the extended address instruction queue is 256 qwords deep and contains the addresses used by the initiator when performing the test. The PCI instruction type and format will be hereinafter described. The starting address is the configuration memory base address+0x1000. This full 64-bit address is OR'ed with the instruction queue's bits (9:0) (63:32) to produce the address generated by the initiator for backward compatibility.

The bit field 63:0 is a read/write and relates to the PCI address (63:0). AD(63:32) is set the dual address cycle and AD (63:36) bits are static in nature. Only AD(35:2) is controlled internally by a counter. Also it will resynchronize to the correct address if the burst transaction is broken up in the middle or to generate the addresses on non-burst transactions.

Finally the configuration alias space referred to above provides a channel for the software to change the various configuration regeisters through the memory space.

The PCI command cycles that are supported as shown in the table below.

| C/BE[3:0)# | Command |
|---|---|
| 0000 | |
| 0001 | Special Cycle |
| 0010 | I/O Read |
| 0011 | I/O Write |
| 0100 | Reserved |
| 0101 | Reserved |
| 0110 | Memory Read |
| 0111 | Memory Write |
| 1000 | Reserved |
| 1001 | Reserved |
| 1010 | Config Read |
| 1011 | Config Write |
| 1100 | Memory Read Multiple |
| 1101 | Dual Address |
| 1110 | Memory Read Line |
| 1111 | Memory Write & |
| | Invalidate |

The following table contains the configuration register information for the test board 100. All specific registers of the board and essential PCI configuration registers are implemented.

| | | | | | | | |
|---|---|---|---|---|---|---|---|
| 31 | 24 | 23 | 16 | 15 | 8 | 7 | 0 |

| 00h | Device ID (007Fh) | | Vendor ID (OE11h) R | |
|---|---|---|---|---|
| | | | (idreg) | |
| 04h | Status Register (R/W) | | Command (R/W) | |
| | | | (cfg_cmd) | |
| 08h | Class Code (FF0000h) R | | | Revision ID |
| | | | | (03h) R |
| OCh | BIST (00) R | Header | Latency | Cache Line |
| | | Type (00) R | Timer (R/W) | Size (00) |
| | | | | R/W |
| 10h | BAR0: Memory Base Address Register (FFE0_0004) (R- | | | |
| | Part W) (membase) | | | |
| 14h | BAR0: Memory Base Address Register (FFFF_FFFF) | | | |
| 18h | BAR1: IO Base Register (FFFF_FF01) (io_base) | | | |
| 20h | BAR2: Configuration Memory Base Address Register | | | |
| | (FFFF_0000) | | | |
| 24h | Base Address Register 6 (0000_0000) Not used | | | |
| 28h | Base Address Register (0000_0000) Not used | | | |
| 2Ch | Sub system id (0001h) | | Vendor ID (OE11h) R | |
| 34h | Capability Pointer 50h | | | |
| 3Ch | Max_Lat(00h)R | Min_Gnt(00h)R | Interrupt | Interrupt |
| | | | Pin (01h) R | Line (FF) |
| | | | (intpin) | (R/W) |
| | | | | (intline) |

| | | | |
|---|---|---|---|
| 50h | Message Control (R/W) | Next Pointer | Capability |
| | | (00h) | ID (05h) |

| | |
|---|---|
| 54h | Message Upper Address (31:0) |
| 58h | Message Lower Address (31:0) |

| | |
|---|---|
| 5Ch | Message Data (15:0) |

| A4h | PCI Master/Slave register (31:0) | |
|---|---|---|
| A8h | Control Register (0) | |
| B0h | Lower Base Data Pattern/Lower Random Seed/Lower | |
| | Toggle Pattern A (63:32) | |
| B4h | Upper Base Data Pattern/Upper Random Seed/Upper | |
| | Toggle Pattern (31:0) | |
| B8h | Lower Incremental Pattern/Toggle Pattern B (63:32) | |
| BCh | Upper Incremental Pattern/Toggle Pattern B (31:0) | |
| C0h | Error Target Address (31:0) | |
| C4h | Error Target Address (63:32) | |
| C8h | Error Target Data Low (31:0) | |
| CCh | Error Target Data High (63:32) | |
| D0h | Reserve | Error Data Count (29:0) |

| D8h | Target Reference Data Low (31:0) | | | |
|---|---|---|---|---|
| DCh | Target Reference Data High (63:32) | | | |
| E0h | Month (BCD) | Date (BCD) | Year (BCD) | Date |
| | | | | Revision |

| | |
|---|---|
| E4h | Private Message Data (31:0) |

The following comments are made in respect of some of the configuration register information.

The Vendor ID (OOH) identifies the Vendor and the device ID identifies the particular device also in location 00h.

Command Register (04h)

The command register controls the ability of the card or board 100 to generate and respond to different access cycles.

Bit field 15:11 is not used;

Bit number 10 represents INTx Disable whereby the value of 1 will disable the setting of the Inta_control in A4 register. It will override the auto INTA_generation;

Bit 9 represents the fast back to back disable represented by 0 and fast back to back enable represented by 1;

Bit 8 when set to one represents the enabling of the SERR# buffer otherwise 0 disables this buffer;

Bit 7 represents the stepping control and is a read only bit and when set to one enables the stepping control. All other bits from 15 down to 0 are read/write.

Bit 6 enables or disables the parity errors, a 0 represents the ignoring parity errors and a 1 represents taking normal action for parity errors;

Bit 5 represents the VGA pallet snoop and is disabled when 0;

Bit 4 when set to 0 creates a memory write instead of a memory write and invalidate and when set to 1 the initiator may generate memory write and invalidate commands. It has a value of 0 at reset;

Bit 3 is set to 0 to ignore special cycles and set to 0 to monitor special cycles;

Bit 2 specifies whether the card can act as an initiator, 0 is for disabling the initiator mode and 1 is for enabling the initiator mode;

Bit field 1 specifies whether the card responds to memory accesses and is set to 0 for disable memory space and set to 1 for enable memory space;

Bit field 0 specifies whether the card responds to I/O accesses (no response to I/O cycles). It is set to 0 to disable I/O space and set to 1 for enabling I/O space.

Bit fields 9, 5, 4 and 3 are all read/write enabled and signify that the logic is implemented but only a dummy write buffer is provided. Bit fields 10, 8, 6, 2, 1 and 0 are R/W and bit field 7 is read only.

The Status Register (06h)

This has 16 bits wherein bit 15 is a 1 to indicate parity error detected, bit 14 is set to 1 to indicate that SERR# is inserted, bit 13 is set to 1 to indicate that Master abort is received (not set by special cycles), bit 12 is set to 1 to indicate that target abort has been received and bit 11 is set to 1 to indicate that target abort has been signalled. All of the bits 15 to 11 are not implemented at this stage and are reset by writing a 1 to this bit position (0).

Bits 10 and 9 indicate the slowest DEVSEL# response which is set to 10. Settings of 00 indicate a fast DEVSEL# and its setting of 01 indicates a medium DEVSEL#.

Bit 8 is set to one to indicate that data parity is detected and is reset by writing 0 to this bit position. At this stage it has not been implemented.

Bit 7 indicates fast back to back capability and is set to 0.

Bit 6 and bit 2:0 are reserved bits. Bit 5 is set to 1 to indicate 66 MHz card on a 66 MHz bus. It is capable bit and gets the value from the board setting.

Bit 4 indicates a capabilities list and is set to 1 to do this and finally bit 3 is an interrupt status and is set to 1 if INTX is enabled or MIS cycle has been completed.

All of bits 15 down to 0 are read only bits.

Referring back to the configuration register information, the class code is set to FF0000h and the revision ID for the board 100 indicates the revision of various PCI test boards created.

At this stage the cache line size is not implemented, the latency timer register specifies the value of the latency timer in units of bus clocks. The header type register identifies the layout of bytes 010h to 3Fh in the PCI configuration header.

The memory base address register is used to assign the memory base address for the board 100. The address space assigned is a variable number of DWORDs. This base is compared when doing memory commands and if the base address matches then the board 100 will accept the memory transfer. The interrupt pin register tells whether or not the function uses the interrupt pin and is an 8 bit field. It is a dummy register defaulted to the value FF.

PCI Master/Slave Register (A4h)

| Bit | | | |
|---|---|---|---|
| field | R/W | Definition | Description |
| 31 | R/W | Disable_read | When this bit is set by |
| | | | software, the data read |
| | | | during an INITIATOR READ |
| | | | cycle will not be compared to |
| | | | the data generated by the |
| | | | internal pattern generator. |
| | | | This bit disables the data |
| | | | pattern verification |
| | | | mechanism |
| 30 | R/W | Ignore_latency | 1=ignore latency timer |
| 29:28 | | Reserved | Reserved |
| 27 | R/W | Inta_reg/MSI | A read value of 1 indicates |
| | | Interrupt | either INTA_or MSI interrupt |
| | | | is asserted. |
| | | | A write of 0 release INTA_and |
| | | | Interrupt Status in |
| | | | Status register for the MSI |
| | | | function. A write of 1 will |
| | | | enable both the MSI interrupt |
| | | | and the INTA_This |
| | | | register hardwires the |
| | | | INTA output to 0 or 1 |
| | | | This register overrides both |
| | | | Intx_disable in the Command |
| | | | Register and the Inta_control |
| | | | in this A4 register |
| 26 | R/W | Intb_reg | 1=INTB_asserted low, should |
| | | | not be used unless INTPIN |
| | | | register is changed. |
| 25 | R/W | Intc_reg | 1= INTC_asserted low, should |
| | | | not be used unless INTPIN |
| | | | register is changed. |
| 24 | R/W | Intd_reg | 1= INTD_asserted low, should |
| | | | not be used unless INTPIN |
| | | | register is changed |
| 23 | R/W | Inta_control | 1= Assert INTA_low at the |
| | | | end of a master reset |
| | | | 0= No automatic assertion of |
| | | | INTA_For |
| | | | automatic assertion of |
| | | | INTA_to occur, the |
| | | | Intx_disable in the Command |
| | | | Register (04h) needs to be 0. |
| 22:21 | | Reserved | Reserved |
| 20 | R | Inta_{—} | Status of interrupt line |
| | | | INTA_{—} |
| 19 | R | Intb_{—} | Status of interrupt line |
| | | | INTB_{—} |
| 18 | R | Intc_{—} | Status of interrupt line |
| | | | INTC_{—} |
| 17 | R | Intd_{—} | Status of interrupt line |
| | | | INTD_{—} |
| 16 | R | PCI64_Slot | PCI64 Slot |
| | | | 1 = 32 bit slot |
| | | | 0 = 64 bit slot |
| 15 | R/W | Copy Down | This bit enables the 64-bit |
| | | Enable | Master to 32-bit target copy |
| | | | down logic |
| 14 | R/W | Req64 Enable | Set by software 1 = 64 bit |
| | | | cycles |
| | | | 0 = 32 bit cycles |
| | | | Written by software to |
| | | | indicate type of slot. Also, |
| | | | Cards look at this bit only |
| | | | to determine type of slot. |
| | | | The core logic uses both the |
| | | | Req64_enable and the Device |
| | | | Type (1:0) to qualify the 64- |
| | | | bit operation for both |
| | | | targets and initiators |
| 13 | R/W | Preserve_Data | Preserve the data pattern |
| | | | between two sets of |
| | | | transactions, the data |
| | | | generator will continue |
| | | | sequentially from first |
| | | | transaction to the second |
| | | | one. In order to use this |
| | | | function, set this bit to 1 |
| | | | before the first set of |
| | | | transaction; this bit needs |
| | | | to maintain a constant of 1 |
| | | | for the second transaction. |
| | | | Simply said, a write of 0 at |
| | | | any instance will reset the |
| | | | Data Generator and destroy |
| | | | the purpose of data |
| | | | preservation. |
| 12 | R | Reserved | Reserved (was m66en status) |
| 11.8 | R/W | w3..w0 | Wait States for PCI cycle |
| | | | i.e. |
| | | | # of IRDY wait states |
| | | | # of TRDY wait states |
| | | | (w3..w0) |
| 7 | R | Master Enable | 1= PCI Master still running, |
| | | | cleared when terminate |
| | | | command reached |
| | | | 0=IDLE |
| 6:5 | R/W | Control | 00 = Normal |
| | | Termination | 01 = Retry |
| | | | 10 = Disconnect |
| | | | 11 = Abort |
| | | | Note: If set for retry, the |
| | | | target will retry default 15 |
| | | | (from A8(27:24)) times and |
| | | | on the next request complete |
| | | | the transaction normally. |
| 4 | R | Slot Type | Senses REQ64# during RESET# |
| | | | 0= 32 bit slot |
| | | | 1= 64 bit slot (If system |
| | | | reset <300 ms then Altera part |
| | | | won't be configured in time |
| | | | for this bit to work. |
| | | | Currently the only fix for |
| | | | this problem is to do a warm |
| | | | boot) |
| 3:2 | R/W | Device Type | Master and Target uses both |
| | | | Device Type and the Req64_enable |
| | | | to qualify the 64-bit |
| | | | operation if it is on a 64- |
| | | | bit bus.. |
| | | | 00 = 32 bit slave |
| | | | 01 = 32 bit Master |
| | | | 10 = 64 bit Slave |
| | | | 11 = 64 bit Master |
| 1 | R/W | Gen SERR_on | 1 = Generate SERR immediately |
| | | | 0 = Allow bits in register A8 |
| | | | to control assertion of SERR |
| 0 | R/W | Gen PERR_on | 1 = Generate Perr_immediately |
| | | | 0 = Allow bits in register A8 |
| | | | to control assertion of PERR_{—} |

Control Register (A8h)

The following table identifies the 32-bits in the bit field for this register.

| Bit | | | |
|---|---|---|---|
| field | R/W | Definition | Description |
| 31:30 | — | Reserved | NI |
| 29 | R/W | End of | The last instruction is |
| | | Queue | completed for the master |
| | | | emulation. |
| 28 | R/W | Data Error | Data Error is detected during |
| | | | the master read operation. |
| | | | Clearing of this bit will reset |
| | | | the Target Data, Target Address |
| | | | and Data Error Count registers |
| | | | to 0s. |
| 27:24 | R/W | Retry | Power on default value = 0xF. |
| | | Counter | If control termination is set |
| | | | to Retry A4[6:5]= 01, then |
| | | | retry this number of times then |
| | | | terminate normally. If this |
| | | | value is 0 then do not retry |
| | | | but instead do a Normal |
| | | | termination. If A4[6:5] is not |
| | | | set to Retry, then this |
| | | | register is a don't care. |
| 23:22 | | Reserved | Reserved |
| 21:20 | R/W | Incr_mode | These two bits control the |
| | | | addition mechanism in the |
| | | | incremental data pattern |
| | | | generation. |
| | | | 0: Addition for the data |
| | | | pattern is performed on a |
| | | | single byte alignment |
| | | | 1: Addition performed on word |
| | | | alignment |
| | | | 2: Addition performed on dword |
| | | | alignment |
| | | | 3: Addition performed on the |
| | | | whole 64-bit quadword |
| 19 | | Reserved | Reserved |
| 18 | R/W | Loop Back | 0= This is the default. The |
| | | Ena | Slave will not respond to the |
| | | | address coming from the Master |
| | | | of the same test board. |
| | | | 1= The Slave is enabled to |
| | | | respond to the address coming |
| | | | from the Master of the same |
| | | | board. When this bit is |
| | | | enabled, the data output in the |
| | | | WRITE or the checking of the |
| | | | incoming data during the READ |
| | | | operations are no longer valid. |
| 17:16 | R/W | Select Data | 0= Select the incremental |
| | | Pattern | pattern mechanism for data |
| | | | generation. |
| | | | 1= Select the pseudo random |
| | | | pattern mechanism for data |
| | | | generation. |
| | | | 2= Select the toggling pattern |
| | | | mechanism for data generation. |
| 15 | R/W | Req Delay | 0= disable toggling of |
| | | Ena | req_deassertion delay |
| | | | 1= allow req_to be disabled |
| | | | with the assertion of frame_, 1 |
| | | | clock before frame_is |
| | | | asserted, or 1 clock after |
| | | | frame_is asserted. The |
| | | | deassertion delay will toggle |
| | | | back and forth automatically |
| | | | after the deassertion of each |
| | | | req_. Below is a table of the |
| | | | internal req_toggle signal and |
| | | | the effect it has on the |
| | | | deassertion of req_. |
| | | | Req_toggle value and function |
| | | | 00- normal 1 clock after frame_{—} |
| | | | 01 - normal 1 clock after |
| | | | frame_{—} |
| | | | 10 - deassert req_with frame_{—} |
| | | | 11 - deassert req_1 clock |
| | | | before frame_{—} |
| 14-10 | R/W | Data_phase | Data phase to cause parity |
| | | | errors, or perr_{—} |
| | | | 0= no errors |
| | | | 1-0x1F= data phase for error |
| | | | to occur |
| 9 | R/W | Par64_data_T | 1= generate bad parity on par64 |
| | | | during specified data phase as |
| | | | a target of a read |
| 8 | R/W | Par_data_T | 1= generate bad parity during |
| | | | specified data phase as a |
| | | | target of a read |
| 7 | R/W | Par64_data_I | 1= generate bad parity on par64 |
| | | | during specified data phase as |
| | | | an initiator of a write |
| 6 | R/W | Par_data_I | 1= generate bad parity during |
| | | | specified data phase as an |
| | | | initiator of a write |
| 5 | R/W | Par64_address_I | 1= generate bad parity on par64 |
| | | | during address phase as in |
| | | | initiator |
| 4 | R/W | Par_address_I | 1 = generate bad parity during |
| | | | address phase as an initiator |
| 3 | R/W | Perr_data_I | 1= generate perr_during |
| | | | specified data phase as an |
| | | | initiator of a read |
| 2 | R/W | Perr_data_T | 1= generate perr_during |
| | | | specified data phase as a |
| | | | target of write |
| 1 | R/W | Serr_address_T | 1= generate serr_during |
| | | | address phase as a target |
| 0 | R/W | START | 1 = Enable the PCI test board to |
| | | | start execution on the |
| | | | Instruction Queue |
| | | | 0= Disable the PCI test board |
| | | | from executing the Instruction |
| | | | Queue |

Lower Base Data Pattern/Lower Random Seed/Lower Toggle Pattern A

This is located at B0h. All 32-bits are read/write and are defined as base data pattern/random seed/toggle A. This register is modified by the Select Data pattern bit in the A8h register. If the data pattern bit is 0, this register represents the base pattern that will be used from the internal incremental pattern generator. If it has a value of 1 this register becomes the seed for the Random Pattern generator. If the data pattern select has a value of 2, the register will become the first register for the toggling pattern generation. For toggle mode in a 32-bit Master, the Toggle Pattern A and the Toggle Pattern B need to be the same 64-bit value. Bit field (31:0) will come up as the first dword and bit field (63:32) will be the second dword. For the toggle mode in a 64-bit Master, the bit field (31:0) of the Pattern A is the first dword. The bit field (63:32) of Pattern A is the second dword, bit field (31:0) of Pattern B is the third dword and the bit field (63:32) of Pattern B is the fourth dword.

Upper Base Data Pattern/Upper Random Seed/Upper Toggle Pattern A (B4h)

This is a 32-bit field read/write capability and is by definition base data pattern/random seed/toggle A (63:32). The Select Data pattern bit in the A8h register is the modifier for this register. If the data pattern is 0 then the register represents the base pattern that will be used for the internal incremental pattern generator. If the data pattern is 1, this register will become the seed for the Random Pattern Generator. If the data pattern select has a value of 2, the register will become the first register for the toggling pattern generation. For toggle pattern, please refer to the earlier description in relation to the lower base data pattern/lower random seed/lower toggle pattern A register.

Lower Increment Pattern/Lower Toggle Pattern B (B8h)

This is also a 32-bit read/write field defined as Increment Pattern/toggle B (31:0). The Select Data pattern bits in the A8h register is the modifier for this register. If the data pattern has a value of 0 then this register will become the delta value for the incremental pattern generator. If the data pattern select has a value of 2 then the register will become the first register for the toggling pattern generation. For the toggle pattern please see the earlier description in relation to the register B0h.

Upper Increment Pattern/Upper Toggle B (BCh)

This is a 32-bit read/write field defined as Increment Pattern/Toggle B (63:32). The Select Data pattern bits in the A8h register is the modifier for this register. If the data pattern is equal to 0 then this register will be the upper delta value for the incremental pattern generator. If the data pattern select has a value of 2, the register will become the first register for the toggling pattern generation. For the toggle pattern please refer to the earlier description in relation to the register location B0h.

Error Target Address Register Low (C0h)

This is a 32-bit read only field defined as a Target Address Register (31:0). While the board 100 is doing a read transaction this register is used for error recording. This register stores the offending address AD(31:0) at the first occurrence of data inconsistency. It is reset by clearing the Data Error bit in the A8h register.

Error Target Address Register High (C4h)

Again this is a 32-bit read only field defined as Target Address Register (63:32). While the board 100 is doing a read transaction this is used for error recording. This register stores the offending address AD(63:32) at the first occurrence of data inconsistency. It is reset by clearing the Data Error bit in A8h register.

Error Target Data Register Low (C8h)

This is a 32-bit read only field defined as Target Data (31:0). Again while the board 100 is performing a read transaction this is used for error recording whereby the register stores the data AD(31:0) of the bus transaction at the first occurrence of data inconsistency. It is reset by clearing the Data Error bit A8h register.

Error Target Data Register High (CCh)

As with the previous register it is a 32-bit read only field defined as Target Data (63:32). Again it is for error recording and it stores the data AD (63:32) of the bus transaction at the first occurrence of data inconsistency. Again, it is reset as before.

Error Data Error Count (D0h)

This is a 30-bit read only field and by definition is Data Error Count (29:0). This counter measures the total number of inconsistent Dwords during the read transactions. It is reset by clearing the data error bit in A8h register.

Target Reference Data Low (D8h)

This is a 32-bit read only field and by definition is Target Reference Data (31:0). This register holds the expected value of the data phase when the first data phase error occurs.

Target Reference Data High (DCh)

This is also a 32-bit read only field and by definition is Target Reference Data (63:32). This register holds the expected value of the data phase when the first data phase error occurs.

Private Message Data (E4h)

This is a 32-bit read/write field defined as Private Message Data (63:32). This register holds the data for the MSI interrupt.

When the peripheral device detects a data error in the process of verifying the data dynamically as it reads the data, it generates a hardware trigger rather than waiting for the system to verify data later. The hardware can also store only the data errors instead of all the data in its internal buffers. Software using this device can then subsequently read these internal buffers to record any errors that the device has detected. The trigger which indicates the inconsistent data between the data generator and the incoming data is flagged using TRIGOUT which is on pin 5 of an E1 connector.

Other indicators provided by the system include CONFDONE which designates that the configuration of the FPGA is successful. There is the MASTER indicator which indicates that the board 100 is running as in initiator. There is the EM_SLAVE indicator which indicates that the board 100 is running as a target. The indicator POWER ACTIVE indicates that the power is on.

In order to support the 64-bit, 66 MHz data transfer capability, the PCI bus 120 implements 40 additional pins. One pin is directed to REQ64_ which is asserted by a 64-bit bus master to indicate that it would like to perform 64-bit data transfers. REQ64_ has the same timing and duration as the FRAME_signal. Another bit is designated ACK64_ which is asserted by a target in response to REQ64_ assertion by the Master, if the target supports the 64-bit data transfers. ACK64_ has the same timing and duration as DEVSEL_, but ACK64_ must not be asserted unless REQ64_ is asserted by the initiator.

32 bits are taken up by AD (63:32) which comprises the upper 4 address/data paths. A further four bits is taken by CBE (7:4) which comprises the upper four command/byte enable signals. A further bit is the parity bit PAR64 that provides even parity for the upper four AD paths and the upper four CBE signal lines. The last of the 40 bits goes to M66EN which is provided as an input to the PCI clock circuit on the system board. If M66EN is sampled as asserted by the clock circuit then it provides a 66 MHz PCI clock.

In order to determine the type of slot, the board 100 installed in 64 bit expansion slot samples REQ64_ asserted on the trailing edge of RST_. This informs that it is connected to the extension pull-ups on the system board and need take no special action to keep the extension from floating when not in use. When the board 100 is installed in a 32 bit card slot, however, it detects REQ64_ deasserted on the trailing edge of RS_. This informs it that it is not connected to the system board—resident pull-ups on the extension signals.

The 66 MHz PCI component or add-in card indicates its support of 66 MHz in two fashions, that is programmatically and electrically. The 66 MHz-CAPABLE bit has been added to the status register.

When the PCI initiator state machine of the data generator engine 118 is used, this occurs after programming the configuration registers. The enable of START bit in the A8h configuration register indicates the start of a PCI cycle. Before starting the test the software programs instructions in the instruction queue. The initiator then the reads the status of the START bit in configuration register A8h and if asserted, the initiator state machine will proceed with issuing a REQ_ or a REQ64_ (assuming the bus is idle) along with the FRAME_ depending on the type of transaction desired. Once the GNT_ and the ACK_/ACK64_ signals are obtained, the initiator reads and executes the instruction from the instruction queue one at a time. At the end of the transaction the card can issue interrupt or MSI to indicate the end of the test.

The data generator will generate data for the write transaction in a purely sequential manner. During the read transaction, the data generator provides reference data to compare to the incoming data. If a mismatch occurs, both the address and the data of the first occurrence of error will be logged and stored in local registers. The internal data generator and the data-pipe can provide O-wait state during burst assuming the target does not introduce a wait state. If wait-state is asserted at the current data phase by the target, the initiator will need to insert a wait-state right after the current data-phase is consumed. This action resynchronizes the internal data-pipe. The data generator can also be set to perform automatic copy-down functions when the 64-bit Master is transferring to a 32-bit target.

The PCI target state machine is activated on an address decode hit. The state machine will claim the transaction by asserting DEVSEL_. The target state machine is programmed to generate slow DEVSEL_. The address is loaded into the local memory address pointer DADDR(18:0) register during a slave cycle. The target state machine can be programmed to provide normal, retry, abort and disconnect functions. Regarding the software used by the system, which is stored in the command memory 116, the software caters for among other things power on self test (POST) requirements, initialisation requirements, and particular programming considerations. For the initialisation requirements, the PCI configuration header memory and base addresses will be initialised with default values from memory during power up. BIOS will change these particular registers to meet system needs and if more than one board 100 is used, it will need to modify the base addresses to unique address ranges. In order to prevent any adverse affects the memory should be initialised once after power up.

When programming the Master for 64-bit cycles, the card will need to be plugged in a 64-bit slot and bit 14 of the A4h control register should be set to 1 which indicates a 64-bit slot and thus permitting 64-bit cycles. When MSI instruction is used, the Single Data Phase bit needs to be disabled and the length/iteration needs to be set to 1.

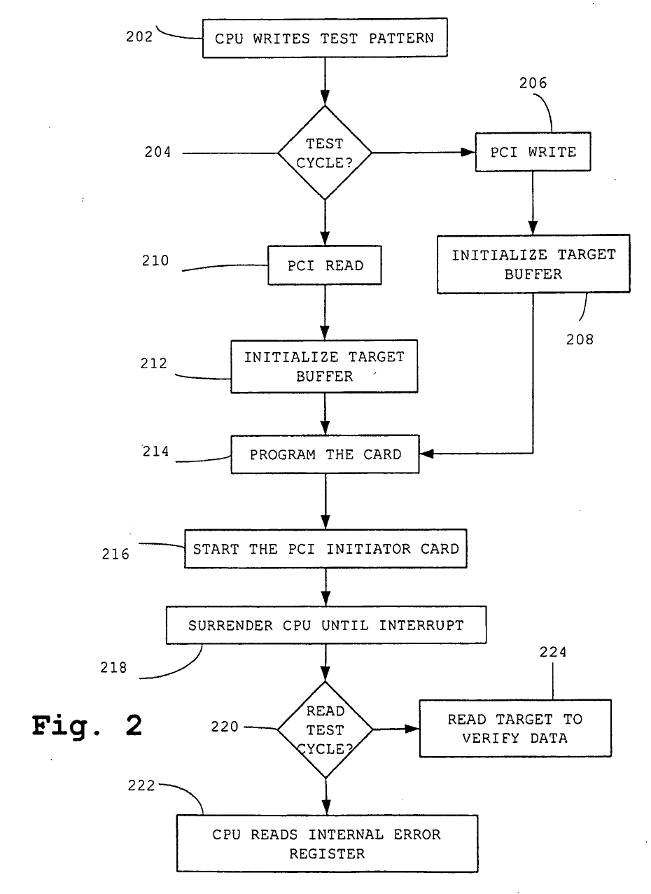

The PCI data generator engine 118, via software, undertakes tests in the following manner. It exercises the PCI initiator reads and writes of the host memory, PCI memory and IO, E/ISA memory and IO sub-systems. As an initiator the data generator may initiate bursts or non-burst cycles. The thread requires at least one test board 100 however additional cards allow for greater utilisation of the system PCI bus 120. The sequence is as follows with reference to FIG. 2. At step 202 the CPU writes a test pattern to the pattern buffer in host memory. At step 204 a decision is made as to which test cycle is being undertaken. If at step 206 the test cycle is any PCI WRITE then at step 208 the target buffer is initialised, the target buffer being either a host memory or a target. The target buffer is initialised to the inverse of the pattern buffer. If at step 210 the test cycle is a PCI READ then the target buffer is initialised to the pattern buffer at step 212. At the next step 214 the card is programmed such that the data generator 118 generates the data dynamically so that it does not have buffers which need to be pre-programmed. This makes it much faster and more bus efficient to initialise and verify. At step 216 the PCI initiator card is started and at step 218 the thread will surrender the CPU until the card or board interrupt is applied. At step 220 if a test cycle was a READ then at step 22 the CPU reads the internal error register in board 100. Otherwise at step 224 the CPU reads the target to verify the data.

Various test options are available to the data generator. This includes PCI initiator tests whereby it undertakes the PCI initiator reads and writes of host memory, PCI memory and IO, E/ISA memory and IO sub-systems. Again as an initiator the board 100 may initiate burst or non-burst cycles.

There is also PCI initiator commands such as dual address cycle, memory write and invalidate (MWI) and IRDY delay from FRAME. The dual address cycle forces cycles to addresses below 4 GB to be Dual Address Cycle to test the chipset support for DAC for systems that support more than 4 GB of memory without requiring the particular system to be equipped with more than 4 GB of memory. This provides some amount of test coverage but adequate verification requires systems to be fully equipped with memory.

The MWI command guarantees full cache line writes and allows a processor to invalidate the modified cache line without writing it back to host memory, since the peripheral device would overwrite the full cache line. The card or board 100 uses the cache line size register to ensure the transfers end on cache line boundaries even if the MLT has expired and the GNT is lost. This is while the boards test thread uses that value to force transfers to start on cache line boundaries and request burst lengths that are cache line multiples. The NT Meatgrinder 3.70 PCIDG driver reads the cache line size register from PCI configuration space so that if BIOS fails to set it correctly one must manually set the register before running Meatgrinder and preferably before the driver is even loaded. The NT Meatgrinder hardware configuration menu displays the cache line register value that Meatgrinder sees.

The IRDY delay from FRAME menus allow the data generator as an initiator to delay the assertion of IRDY from FRAME. The PCI 2.1 requires the assertion of FRAME within 8 clocks from IRDY. Some PCI targets function properly only when IRDY is asserted within that constraint.

The data generator or PCIDG can burst up to two GB, however typical bursts will be limited to one or more pages (4 KB on x86 and 8 KB on IA64) due to physical memory fragmentation.

The data generator can either abide by its Master Latency Timer (MLT) and surrender the PCI bus on the timer expiration during a burst if GNT has been removed. However the data generator can ignore its latency timer and impose long transfers, possibly at the expense of devices that have real-time latency requirements.

Another option is to generate and specify the number of SERR, PERR, address and data parity as part of the initiator error generation. With regard to PCI Target Responses, this allows the user to specify the assertion of STOP for the response type. This is regardless of whether a data generator card generates ACK64, the TRDY delay from FRAME and the retry counter for a data generator. PCI 2.1 requires a maximum target latency of 8 clocks after the initial data phase as mentioned previously.

There is an option to choose a transfer size available from sequential, random or fixed size transfers. There is also an option to align memory transfers on any Dword or quardword within a cache line.

The particular test cycle that the initiator uses is as follows:

PCIDG initiator: (Card card number, [DAC] command [Non-Burst|Burst] clockcount IRDY, [Fixed REQ|Toggling REQ], byte count Align, width-bit transfer size Bytes [Ignore MLT]->Target.

A special note for Windows 2000/XP users is that a large memory is required to test memory above 4 GB. For Windows 200/XP this may be Advanced Server up to 8 GB and Datacenter up to 64 GB. The data generator is not able to cross a 64 GB boundary with one instruction.

When the board is configured to respond as a Master or initiator device the particular initiator feature highlights include:

The initiator uses data pattern generators for both read/write data transactions. Three different generators may be used, random, incremental or toggle. There is support for very long burst transfer up to 4 GB. There is adjustable IRDY_wait states for each data phase during the transaction. The user can select to turn-on the automatic copy-down feature (64-bit initiator to 32-bit target mechanism). All byte enable combinations during the data transaction includes starting pattern, ending pattern and the main body pattern. All command combinations are supported. The initiator can assert PERR_at a specified data phase from the read transaction. The initiator can generate a PAR or PAR64 errors at specified data phase for the write transaction. The initiator can generate PAR or PAR64 error at the address phase. Data error detection logs the offending address, the faulty data and the expected data at the first occurrence of the error. A user can select different REQ_ termination schemes.

When the board 100 is configured to respond as a slave or target device the particular target features include:

The target contains 4 MB of memory space and 256 KB of I/O space. The target can be configured as either a 32 or 64-bit device. There are adjustable TRDY_wait states for each data phase in the transaction. There are adjustable DEVSEL_responses (medium). The target can be configured to respond in retry, abort or disconnect. The target can also assert PERR_or SERR_when the card is addressed as the target. It can assert PERR_or SERR_immediately through the configuration write. The target can generate PAR or PAR64 error at a specified data phase during the read cycle. The user can inject data error through the Test_in button.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A peripheral device to generate read and write cycles on a PCI bus, the device comprising:
a PCI bus interface, and
a control unit having a data pattern generator to source a data pattern to a target via the interface during a write operation and to verify an incoming data pattern from the interface during a read operation.

2. A peripheral device as claimed in claim 1, wherein the data pattern generator is operable to sequentially generate a preselected test pattern for comparison bit by bit with an incoming data pattern as it is being received from the PCI bus via the PCI bus interface to verify a read operation.

3. The peripheral device as claimed in claim 2, further comprising a memory to store a data pattern.

4. The peripheral device as claimed in claim 3, wherein the stored data pattern is written to another peripheral device for comparison with a test pattern generated by that other device to verify the read operation of that other device.

5. The peripheral device as claimed in claim 3, wherein the stored data pattern is written to an external processor for comparison with an inverse pattern to test the write operation of the peripheral test device.

6. The peripheral device as claimed in claim 3, wherein the control unit is programmed with Master and Slave state machines.

7. The peripheral device as claimed in claim 6, wherein the Master state is implemented to test a read operation of that peripheral device.

8. The peripheral device as claimed in claim 6, wherein the Slave state is implemented to test a read operation of another peripheral device.

9. The peripheral device as claimed in claim 6, wherein the Slave state is implemented to test a write operation of that peripheral device.

10. A method for verifying read cycles on a PCI bus, the method comprising
sequentially generating a preselected test pattern; and
comparing the pattern bit by bit as it is generated with an incoming data pattern as it is being received from the PCI bus.

11. A computer program for verifying data read cycles on a PCI bus, the computer program comprising code operable to
sequentially generate a preselected test pattern; and
to compare the pattern bit by bit as it is generated with an incoming data pattern as it is being received from the PCI bus.
